(19) United States
(12) Patent Application Publication
(10) Pub. No.: US 2002/0079909 A1
(43) Pub. Date: Jun. 27, 2002

(54) Output protected energiser

(75) Inventor: Jack Hartstone Reeves, Hamilton (NZ)

Correspondence Address: YOUNG & THOMPSON, 745 SOUTH 23RD STREET 2ND FLOOR, ARLINGTON, VA, 22202

(73) Assignee: Tru-Test Limited, AUCKLAND (NZ)

(21) Appl. No.: 10/055,077

(22) Filed: Jan. 25, 2002

(30) Foreign Application Priority Data
Dec. 21, 2000 (NZ) 509061

(51) Int. Cl. G01R 27/26

(52) U.S. Cl. 324/677

(57) ABSTRACT

An electric fence energiser for coupling to an electric fence line. The energiser includes a sensor to sense the load on the fence line, at least one storage capacitor, and a charge circuit to charge the storage capacitor(s). A control circuit provides an output pulse with energy appropriate to the sensed load and determines whether the current pulse will exceed a predetermined limit adjustment and adjust the output pulse to send out an output pulse with voltage and/or energy below the predetermined limit if the current pulse will exceed said limit.

### FIELD OF INVENTION

The present invention relates to an electric fence energiser arranged to produce output pulses that fall within required safety standards during rapid decreases in the fence line load.

### BACKGROUND TO THE INVENTION

Energisers that control the level of the energiser output pulses proportional to the load on the fence line are currently available. Typically such energisers sense the load on the fence line during one pulse and adjust the voltage of the next output pulse dependent on the sense load. However these energisers whilst complying with output safety standards are capable of delivering pulses outside the limits given in safety standards if rapid decreases in load occur.

Output controlled energisers operate by checking the voltage of the last pulse. If this is lower than the designed performance for the sensed load the energiser control system increases the voltage of the next pulse, (usually by increasing the level of energy stored on the capacitor(s) of the energiser), to be discharged in the next pulse. When the next pulse is initiated the load on the fence line during that pulse is again sensed and the stored energy again adjusted as necessary to approach the designed optimum output voltage/energy. These control steps are repeated until the desired optimum output voltage/energy is attained for the sensed load. Typically if small load changes occur the system compensates with small changes to the stored energy and output voltage. However a disadvantage is that if at any time the energiser is operating into a heavy load (say 100 ohms) and has reached a high level of stored energy to have good performance into this load and then the load suddenly reduces the energiser having stored energy for a next pulse to be delivered into a relatively heavy 100 ohm load will still deliver the next pulse into the lighter load of say 500 ohms, at a voltage/energy level which far exceeds the limits required by safety standards. Such a rapid change in load can also occur when a section of an electric fence is switched off for example.

### SUMMARY OF THE INVENTION

In broad terms in one aspect the invention comprises a method of operating an electric fence energiser comprising the steps of sensing the load on a fence line connected to the energiser arranging the energiser to provide an output pulse of appropriate voltage and/or energy for the load sensed during a previous pulse, determining whether the voltage and/or energy in the current output pulse will exceed a predetermined limit, and if the voltage and/or energy in the current output pulse will exceed said limit then modifying the current output pulse to have voltage and/or energy below said limit.

Whether the voltage and/or energy in the current pulse will exceed a predetermined limit such as a safety standard may be determined by a number of methods, including determining the load during the current pulse and comparing the load in the current pulse to the load in the previous pulse—if the comparison shows a significant decrease then the current output pulse will exceed safety standards and the energiser will shunt energy away from the output transformer to prevent this occurring or determining the load at some time during the current pulse and modifying the remainder of the current pulse to ensure the output energy, voltage or current does not exceed the safety standard limit. Another method involves setting a voltage, current or energy level based on the load determined in the previous pulse and determining whether the current output pulse exceeds any of these levels—if the output pulse exceeds any of the levels the energiser will shunt energy away from the output transformer to prevent a pulse being sent out that exceeds safety standards.

Another method involves discharging a single capacitor from a bank of two or more capacitors, determining the load at the time of the current pulse and discharging all, some, or none of the remainder of the capacitors depending on the sensed load.

The load on the fence line may be sensed or determined using a tertiary winding on the output transformer of the electric fence energiser. Other methods for determining the load on the fence line include using sense pulses prior to the output pulse and measuring the load on the fence line during the sense pulse, measuring the rise in the voltage of the output pulse or measuring the output pulse current or energy at a predetermined time during the pulse. Other methods for sensing the load on the fence line may also be used.

During the current pulse the load may be determined by sampling the voltage on a tertiary winding of the output transformer during the first part of the output pulse. Alternatively the rise in output voltage during the first part of the output pulse may be measured or a low power sense pulse may be sent immediately prior to sending the output pulse and the load may be determined during the sense pulse. Other methods for determining the load on the fence line during the current pulse include measuring the pulse current or energy at a predetermined time.

The energy of the output pulse may be adjusted by a number of different means. If the pulse energy is stored in more than one storage capacitor the energy in the output pulse may be adjusted by switching a capacitor or capacitors out of the discharge circuit, or not switching certain capacitors into the discharge circuit, so that the energy in that capacitor or those capacitors is not discharged into the output transformer and does not form part of the output pulse. Another alternative is to shunt energy away from the primary of the output transformer or to short the secondary of the output transformer. The shunted energy may be shunted into an impedance device such as a resistor. Energy may also be shunted away from the secondary of the output transformer. Again impedance circuits may be used for shunting away excess energy. Excess energy may also be shunted into a storage capacitor for storage until required.

In broad terms in another aspect the invention comprises an electric fence energiser comprising a sensor to sense the load on the fence line, at least one storage capacitor, a charging circuit to charge the storage capacitor(s), means arranged to provide an output pulse with energy appropriate to the load sensed during the previous pulse, means arranged to determine whether the current pulse will exceed a predetermined limit, and means arranged to adjust the current output pulse to modify the current output pulse to have voltage and/or energy below the predetermined limit if the current output pulse will exceed said limit.

The means arranged to determine whether the current pulse will exceed said limit such as a safety standard may be load sensing means or means arranged to determine whether a characteristic of the current pulse exceeds a predetermined level.

The means arranged to determine the load on the fence line and the means arranged to determine the load during the current pulse may be the same. The load in each case may be sensed through a tertiary winding on the output transformer, sense pulses, through a measurement in the rise of the output pulse voltage, current or energy or using other known methods.

The energiser may further include an impedance circuit on either the primary or secondary side of the output transformer into which excess energy is shunted. Alternatively a separate winding on the output transformer may be dedicated for this purpose with a switching means and impedance to shunt away excess energy. Alternatively again the energiser may include a switchable circuit arranged so that when switched in the secondary winding of the output transformer is shorted or is connected to an impedance device that dissipates the energy or stores it for later use.

### BRIEF DESCRIPTION OF DRAWINGS

Preferred forms of energiser and method of the invention will be further described with reference to the accompanying drawings by way of example only and without intending to be limiting, wherein:

FIG. 1 is a block diagram showing one preferred form energiser of the invention;

FIG. 2 is a block diagram showing a second preferred form energiser of the invention, and

FIG. 3 is a block diagram showing a third preferred form energiser of the invention.

### DETAILED DESCRIPTION OF PREFERRED FORMS

Ideally the voltage and/or energy level sent along an electric fence line in each pulse changes as the sensed load on the fence line changes so that the most effective shock is given to any animal in contact with the fence line. This is usually achieved by sensing the load on the fence line and changing the voltage and/or energy of the next pulse in proportion with the sensed load. As the load increases, for example as grass and weed growth comes into contact with the fence line, the voltage and/or energy of the output pulses is increased. However there is a one pulse delay between sensing the load and sending out a pulse with voltage and/or energy level appropriate to the load. This does not create problems when the load is increasing as the animals in contact with the fence line will be shocked by a pulse with voltage and/or energy lower than the maximum allowed by safety standards, but if the load decreases during the period between pulses the next pulse can be at too high a level and may exceed safety standards.

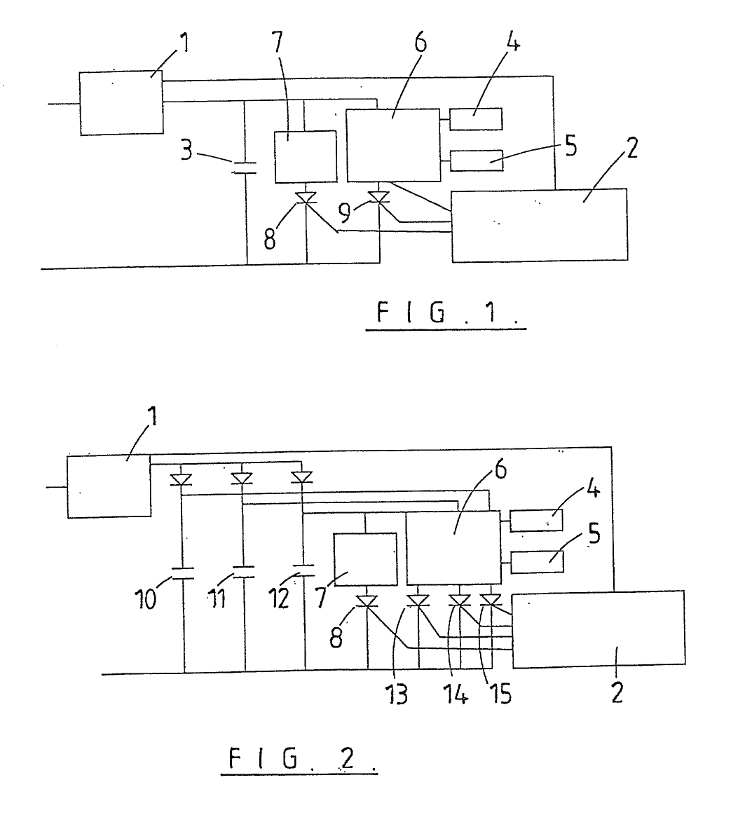

Referring to FIG. 1 a preferred form energiser of the invention includes an energy shunt circuit 7 on the primary side of the output transformer 6. This circuit is used to shunt excess energy intended for an output pulse but not required.

Power is supplied through power supply 1 and may be mains power, battery power or solar power for example. Output pulse energy is supplied to the electric fence 4 through output transformer 6. To provide a pulse to the electric fence, power from power supply 1 is stored in storage capacitor 3. Storage capacitor 3 is shown as a single capacitor but may be more than one capacitor. When storage capacitor 3 is charged to the appropriate level control system 2 switches controllable switch 9 which is typically an SCR to discharge storage capacitor 3 into output transformer 6 and send a pulse to the fence line. Energisers are generally arranged to deliver a pulse into the electric fence approximately every second.

Control system 2 senses the load on the fence line and at each pulse controls the charging of capacitor 3 to a level proportionate to the load. Capacitor 3 may be fully charged for each pulse cycle and partially discharged or may be partially charged for each pulse cycle and fully discharged. In many currently available energisers once control system 2 has determined the load and controlled the charging of capacitor 3 the control system controls the discharge of capacitor 3 so that a pulse is sent along fence line 4 appropriate to the sensed load. This involves a one pulse delay as the load is sensed on the pulse previous to the pulse sent with energy appropriate to the sensed load. As described above this can cause excessively high pulses to be sent along the fence line in some situations.

The control system is arranged to also sense the load during the first part of each output pulse, for example the first 40 to 60 micro-seconds of a 250 micro-second pulse. This may be achieved by use of a tertiary winding on the output transformer of the energiser of the invention or by other means, such as a current or voltage sensing means in the primary or secondary circuit of the output transformer. Whether the current pulse will exceed safety standards may also be sensed by determining the rise in voltage, current or energy of the output pulse during the first part of the output pulse or at a predetermined time during the pulse. Another sensing means involves setting up a level in the control system and monitoring the output pulse voltage level to determine whether the voltage of the output pulse exceeds the predetermined level. If the output pulse voltage exceeds the predetermined level this indicates that the load on the fence line has dropped significantly.

If the control circuit senses that the load on the fence has dropped and that the current output pulse will fall outside safety standards the control circuit of the energiser activates switching device 8 to shunt energy away from the output transformer and into the energy shunt circuit 7. Control circuit 2 may also activate switching device 9 to stop energy from flowing through the circuit from capacitor 3 to output transformer 6. The control system 2 may be arranged to determine the load during the current pulse, the optimum voltage and/or energy for the determined load and the voltage and/or energy already sent in the current pulse. If control system 2 is arranged to calculate the voltage and/or energy sent in the current pulse after determining the optimum voltage and/or energy for the load the control system may be arranged to operate switching devices 8 and 9 to deliver the optimum voltage and/or energy into the load in the current pulse. However if the control system determines that the voltage and/or energy in the current pulse will be above safety standards the control system may immediately activate switching devices 8 and 9 to prevent excess voltage and/or energy forming the current output pulse and to shunt the excess energy into energy shunt circuit 7. This second method will result in a lower than optimum pulse being sent along the fence line. The pulse after this lower pulse will be closer to the optimum pulse if no sudden change in load occurs between the pulses.

Energy dump load 7 may comprise a shunt resistor or other impedance device. The energy dump load may also be a capacitor or bank of capacitors. If the energy dump load is a capacitor or capacitor bank energy shunted into these devices may be used to charge storage capacitor 3 at a later time.

FIG. 1 shows energy shunt circuit 7 on the primary side of output transformer 6. In other embodiments the energy shunt circuit may be located on the secondary side of the output transformer. In this case the energy shunt circuit is still connected in series with a switching device, the switching device being controlled by control circuit 2. One form of energy shunt circuit on the secondary of the output transformer is an impedance circuit that may be switched into the circuit on the secondary of the transformer. Another form of energy shunt circuit is a switchable short circuit.

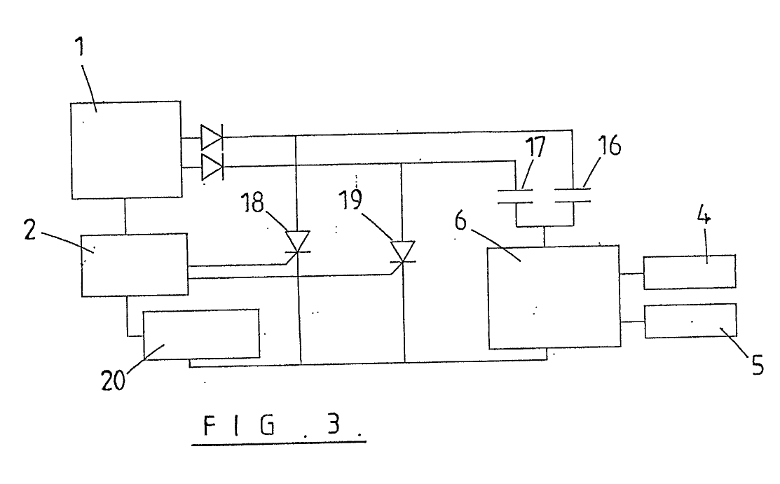

FIG. 2 shows a second preferred form energiser of the invention. This energiser includes a control circuit, power supply and energy shunt load similar to the circuit of FIG. 1. The output transformer includes three primary windings each receiving power from one of the three storage capacitors. Control circuit 2 controls which of storage capacitors 10, 11 and 12 discharge into output transformer 6 through switching devices 13, 14 and 15. In this circuit there are three storage capacitors and primaries on the output transformer but that there may be more than three or only one or two storage capacitors and corresponding transformer primaries and three is used as an example. There may also be only one primary with two or more capacitors all controlled by separate switches.

Control circuit 2 of the energiser senses the load on the fence line and the optimum output voltage and/or energy for the sensed load. The load may be determined by various sensing means such as from a tertiary winding on the output transformer or by monitoring the discharge current in the primary or secondary of the transformer as referred to previously. Once the optimum voltage and/or energy for the load is determined control circuit 2 activates switches 13, 14 and 15 to allow energy from the storage capacitors to discharge into output transformer 6. Capacitors 10, 11 and 12 may be fully charged in each cycle and discharged only as switching devices 13, 14 and 15 are activated or may be only partially charged in each cycle and discharged only as switching devices 13, 14 and 15 are activated or may be only partially charged in each cycle and full discharged. If control circuit 2 determines that the output pulse will exceed the load in the current pulse, the control circuit activates switching device 8 to shunt excess energy into energy shunt circuit 7. Alternatively the control circuit may activate the switching devices so that only one storage capacitor discharges into the output transformer during the current pulse. In this case the control circuit may also activate switching device 8 to shunt energy into energy shunt circuit 7. As described above energy shunt circuit 7 may include an impedance device such as a resistor or may include a capacitor. The energy shunt circuit may also be located on the secondary side of output transformer 6.

FIG. 3 shows a third preferred form energiser of the invention. This energiser includes a control circuit and power supply similar to the circuits of FIGS. 1 and 2. The output transformer is a standard transformer with primary and secondary windings. The output transformer may have a tertiary winding used to sense the load on the fence line. Control system 2 is arranged to control the switching of capacitors 16 and 17 into the output circuit through switching devices 18 and 19. In this circuit only two capacitors are illustrated, but this is by way of example only and more capacitors (and associated switching devices) may be used.

Output sense means 20 of the energiser senses the load on the fence line and control system 2 determines the optimum voltage/energy output for the sensed load. For each pulse the capacitors are fully charged by power supply 1. The control system then activates one switching device to discharge one capacitor through the output transformer. During discharge of the capacitor the output voltage/energy is sensed by sensing means 20. If the first capacitor is fully discharged before the optimum output voltage/energy is reached then, after a preselected delay, the control system may activate the second switching device to discharge the second capacitor through the output transformer. This process can be repeated if there are more than two capacitors in the energiser. If however there is a sudden reduction in load between the load sensed for the previous pulse and the load on the current pulse, the output voltage would rise rapidly during discharge of the first capacitor and this rise would be sensed by sense means 20. If the rise in output voltage is such that the optimum voltage/energy will be reached before delay to fire the second capacitor the control system will prevent firing of additional capacitors and may activate the first switching device to stop the discharge of the first capacitor when the optimum output voltage/energy has been reached.

An alternative to fully charging all capacitors before each pulse is to charge a number of the capacitors to the optimum voltage/energy. When sequentially discharged the capacitors will produce the optimum voltage/energy for the previously sensed pulse. If the load has reduced between pulses and is sensed by the sense means during the current pulse then the control circuit can stop some of the capacitors discharging through the output transformer.

Other methods for charging and discharging the capacitors such as charging the first capacitor to produce the optimum voltage/energy for the load on the previous pulse and fully charging other capacitors can also be used with the energiser of FIG. 3.

It will be appreciated that although the switching devices shown in FIGS. 1, 2 and 3 are SCRs other suitable switching devices may be used.

In other embodiments the energiser may be arranged to sense the load in the first part of each output pulse. The sensed load may be stored in memory. In the next pulse the load on the fence line is again sensed. The load is stored in memory and compared to the load during the previous pulse. If the load has decreased between pulses the energiser may activate a switching device to shunt energy into an energy shunt circuit to avoid sending out an output pulse with more power than allowed by safety standards. The load from the previous pulse can then be removed from memory.

Another method for determining the load on the fence line is through the use of sense pulses. Sense pulses are typically low in power and are sent immediately before an output pulse. The load on the fence line is determined during the sense pulse and the control circuit then determines the optimum output pulse characteristics and activates the switching devices to produce the optimum output pulse. Alternatively the load on the sense pulse can be used to determine whether it will be necessary to shunt any energy during the next output pulse. The time between sending a sense pulse and an output pulse may be of the order of milliseconds or micro-seconds. The purpose of the sense pulse is to reduce the time between sensing the load on the fence line and sending out a pulse with optimum shocking power for the sensed load or to determine whether some energy in the next output pulse will need to be shunted.

The energisers of the invention are arranged to sense whether the load measured on the previous pulse and the load on the fence line during the current pulse are different. The energiser may be arranged to modify the output pulse if the difference in the loads are greater than a predetermined value, say 50 ohms, or when the difference in the loads is greater than a certain percentage of the earlier sensed load. For example if the difference between the load measured on a first pulse and the load measured on a second pulse is greater than 10% of the load determined on the first pulse the energiser may modify the output pulse to reduce energy during the second pulse. It will be appreciated that the values given are by way of example only.

The energiser may also be arranged to set a voltage, current or energy level based on the load on the previous pulse. If the current output pulse rises above the preset level this indicates a decrease in load between the pulses. The energiser then activates the energy shunting circuits through switching devices. This last method involves no direct sensing of load during the current pulse but rather sensing that the pulse voltage/energy will be above safety standards.

The foregoing describes the invention including a preferred form thereof. Alterations and modifications as will be obvious to those skilled in the art are intended to be incorporated within the scope hereof.

What is claimed is:

1. A method of operating an electric fence energiser comprising the steps of sensing the load on a fence line connected to the energiser, arranging the energiser to provide an output pulse of appropriate voltage and/or energy for the load sensed during a previous pulse, determining whether the voltage and/or energy in the current output pulse will exceed a predetermined limit, and if the voltage and/or energy in said current output pulse will exceed said limit then modifying the current output pulse to have voltage and/or energy at or below said limit.

2. The method according to claim 1 wherein the load is determined during said current output pulse and compared to the load in the previous pulse.

3. The method according to claim 2 wherein if the comparison shows a significant decrease in load the energiser shunts energy away from the output transformer.

4. The method according to claim 1 wherein if the output pulse exceeds any of said levels the energiser shunts energy away from the output transformer to prevent a pulse being sent out that exceeds said limit.

5. The method according to claim 1 wherein the load on the fence line is sensed or determined using a tertiary winding on the output transformer of the electric fence energiser.

6. The method of claim 1 wherein the load on the fence line is determined using sense pulses prior to the output pulse and measuring the load on the fence line during the sense pulse.

7. The method according to claim 1 wherein the load on the fence line is determined by measuring the rise in the voltage of the output pulse or measuring the output pulse current or energy at a predetermined time during the pulse.

8. The method according to claim 1 wherein during the current output pulse the load is determined by sampling the voltage on a tertiary winding of the output transformer during the first part of the output pulse.

9. The method according to claim 1 wherein the rise in output voltage during the first part of an output pulse is measured or a low power sense pulse is sent immediately prior to sending the output pulse and the load is determined during the sense pulse.

10. The method according to claim 1 wherein the load on the fence line is determined during the current output pulse by measuring the pulse current or energy at a predetermined time.

11. The method according to claim 1 wherein pulse energy is stored in more than one storage capacitor and the energy in the output pulse is adjusted by switching out or not switching in a capacitor or capacitors so that the energy in that capacitor or capacitors is not discharged into the output transformer and does not form part of the output pulse.

12. The method according to claims 2 or 12 wherein if the comparison shows a significant decrease in load the energiser switches out or does not switch in a capacitor or capacitors so that the energy in that capacitor or capacitors is not discharged into the output transformer and does not form part of the output pulse.

13. The method according to claim 3 or 5 wherein energy is shunted away from the primary or secondary of the output transformer or the secondary of the output transformer is shorted to adjust the energy in the output pulse.

14. The method according to claim 13 wherein the shunted energy is shunted into an impedance device.

15. The method according to claim 12 wherein at least one impedance circuit is used for shunting away excess energy.

16. The method according to claim 12 wherein energy is shunted into a storage capacitor for storage until required.

17. An electric fence energiser comprising a sensor to sense the load on a fence line coupled to the electric fence energiser, at least one storage capacitor, a charging circuit to charge the storage capacitor(s), means arranged to provide an output pulse with energy appropriate to the load sensed during a previous pulse, means arranged to determine whether the current output pulse will exceed a predetermined limit, and means arranged to adjust the current output pulse to modify the current output pulse to have voltage and/or energy below the predetermined limit if the current output pulse will exceed said limit.

18. An electric fence energiser as claimed in claim 17 wherein the sensor to determine whether the current output pulse will exceed said limit is a load sensing means or is arranged to determine whether a characteristic of the current output pulse exceeds a predetermined level.

19. An electric fence energiser as claimed in claim 17 wherein the load in each case is sensed through a tertiary winding on the output transformer energy.

20. An electric fence energiser as claimed in claim 17 wherein the load in each case is sensed using sense pulses.

21. An electric fence energiser as claimed in claim 17 further including an impedance circuit on either the primary or secondary side of the output transformer into which excess energy is shunted.

22. An electric fence energiser as claimed in claim 17 further including a separate winding on the output transformer and a switching means and impedance to shunt away excess energy.

23. An electric fence energiser as claimed in claim 17 further including a switchable circuit arranged so that when switched in the secondary winding of the output transformer is shorted or shunted into an impedance device.

24. An electric fence energiser as claimed in claim 17 wherein the load in each case is sensed through a measurement in the rise of the output pulse voltage, current or energy.
